(19) United States
(12) Patent Application Publication
(10) Pub. No.: US 2016/0343975 A1
(43) Pub. Date: Nov. 24, 2016

(54) OLED PACKAGE METHOD AND OLED PACKAGE STRUCTURE

(71) Applicant: SHENZHEN CHINA STAR OPTOELECTRONICS TECHNOLOGY CO., LTD., Shenzhen, Guangdong (CN)

(72) Inventors: Yawei LIU, Shenzhen, Guangdong (CN); Yifan WANG, Shenzhen, Guangdong (CN)

(73) Assignee: Shenzhen China Star Optoelectronics Technology Co., Ltd., Shenzhen, Guangdong (CN)

(21) Appl. No.: 14/423,706

(22) PCT Filed: Feb. 8, 2015
(86) PCT No.: PCT/CN2015/072474

§ 371 Date: Feb. 24, 2015

(30) Foreign Application Priority Data
Dec. 2, 2014 (CN) 201410725111.9

(51) Int. Cl. H01L 51/52; H01L 51/56

(52) U.S. Cl. CPC H01L 51/5246; H01L 51/56; H01L 51/5259

(57) ABSTRACT

The present invention provides an OLED package method and an OLED package structure. The OLED package method, comprising steps of: step 1, providing a package cover plate (1) and a substrate (2) having an OLED element (21), and a circle of glue coating area (10) is pre-formed on the package cover plate (1); step 2, implementing surface roughening treatment to the glue coating area (10) of the package cover plate (1) to obtain a circle of roughened surface (11); step 3, coating a circle of seal (12) on the roughened surface (11); step 4, coating a liquid dryer layer (13) on the package cover plate (1) at an inner side of the seal (12); step 5, oppositely laminating the package cover plate (1) and the substrate (2) and curing the seal (12) to bond the package cover plate (1) and the substrate (2) for accomplishing the package to the OLED element. The method can significantly promote the bonding force between the package cover plate and the substrate and raise the tightness.

### FIELD OF THE INVENTION

The present invention relates to a display technology field, and more particularly to an OLED package method and an OLED package structure.

### BACKGROUND OF THE INVENTION

In the display technology field, flat display panel technologies, such as the Liquid Crystal Display (LCD) and the Organic Light Emitting Diode (OLED) have been gradually replaced the CRT displays. The OLED possesses many advantages of outstanding properties of self-illumination, low driving voltage, high luminescence efficiency, fast response, high clarity and contrast, near 180° view angle, wide range of working temperature, applicability of flexible display and large scale full color display, and has been widely applied in cellular phone screens, computer displays, full color TV, etc. The OLED is considered as the most potential display technology in the industry.

The OLED comprises an anode, an organic emitting layer and a cathode sequentially formed on a substrate. The biggest problem and defect which restrict the development of the OLED industry are the short lifetimes of the OLEDs. The reason why the lifetimes of the OLEDs are shorter is that the electrodes and emitting light layer organic material mainly constructing OLED elements are very sensitive to the pollution, water vapor and oxygen in the atmosphere. In the environment containing water vapor and oxygen, the electric chemical corrosion can easily occur and cause damage to the OLED element. Therefore, the OLEDs require effective package to prevent the entrance of the water vapor and oxygen into the insides of the OLEDs.

The OLED package mainly comprises several ways: dryer package, UV glue package (Dam only package), UV glue and filling glue package (Dam & Fill package) Glass glue package (Frit package), etc. The UV glue package is the earliest and most common OLED package. It has properties below: no solvent or tiny solvent is used to reduce the pollution to the environment; less power consumption, low temperature curability is adaptable for the UV sensitive material; fast curing and high efficiency is applicable for the high speed production line, and the curing equipment merely occupies small space, etc. However, the sealant used in UV glue package is organic material and the molecular gaps after curing are larger. As utilizing the traditional OLED package method, the sealant has drawbacks of curing defects, porosity, weak bonding force with the package cover plate, thus, the water vapor and oxygen permeate into the internal package space through the gaps more easily. Accordingly, the performance degenerates faster and the lifetime is shortened.

Therefore, by effective package to the OLED, the well tightness for the inside of the OLED element can be ensured to diminish the contact with the oxygen and water vapor in the external environment as possible as it can. It is crucially important to stabilize the performance of the OLED element and extend the usage lifetime of the OLED.

At present, the package technology of the OLED element has become the point of the domestic and foreign related researches.

### SUMMARY OF THE INVENTION

An objective of the present invention is to provide an OLED package method, capable of significantly promoting the bonding force between the package cover plate and the substrate and raising the tightness to effectively diminish the oxygen and the water vapor permeating to the inside of the OLED. Accordingly, the performance of the OLED element is promoted and the usage lifetime of the OLED element is extended.

Another objective of the present invention is to provide an OLED package structure, capable of firmly bonding the package cover plate and the substrate. The tightness result is better and the oxygen and the water vapor permeating to the inside of the OLED can be effectively diminished. Accordingly, the performance of the OLED element is promoted and the usage lifetime of the OLED element is extended.

For realizing the aforesaid objectives, the present invention provides an OLED package method, comprising steps of:

step 1, providing a package cover plate and a substrate having an OLED element, and a circle of glue coating area is pre-formed on the package cover plate;

step 2, implementing surface roughening treatment to the glue coating area of the package cover plate to obtain a circle of roughened surface;

step 3, coating a circle of seal on the roughened surface;

step 4, coating a liquid dryer layer on the package cover plate at an inner side of the seal;

step 5, oppositely laminating the package cover plate and the substrate and curing the seal to bond the package cover plate and the substrate for accomplishing the package to the OLED element.

Both the package cover plate and the substrate are glass substrates.

The roughened surface in the step 2 is obtained by wheel grating or flannelette grating.

The roughened surface comprises irregular friction marks pitted at a surface of the package cover plate.

A depth of the roughened surface is not more than 50 μm.

The seal in the step 5 is cured by ultraviolet light irradiation.

The present invention further provides an OLED package structure, comprising a package cover plate, a substrate oppositely positioned with the package cover plate, an OLED element, positioned inside the package cover plate and the substrate and set on the substrate, seal, positioned at periphery of the OLED element to bond the package cover plate and the substrate, a liquid dryer filling at an inner side of the seal and covering the OLED element; a circle of roughened surface after surface roughening treatment is on the package cover plate, and the seal is positioned on the roughened surface.

The roughened surface comprises irregular friction marks pitted at a surface of the package cover plate.

A depth of the roughened surface is not more than 50 μm.

Both the package cover plate and the substrate are glass substrates.

The present invention further provides an OLED package structure, comprising a package cover plate, a substrate oppositely positioned with the package cover plate, an OLED element, positioned inside the package cover plate and the substrate and set on the substrate, seal, positioned at periphery of the OLED element to bond the package cover plate and the substrate, a liquid dryer filling at an inner side of the seal and covering the OLED element; a circle of roughened surface after surface roughening treatment is on the package cover plate, and the seal is positioned on the roughened surface;

wherein the roughened surface comprises irregular friction marks pitted at a surface of the package cover plate;

wherein both the package cover plate and the substrate are glass substrates.

The benefits of the present invention are: the present invention provides an OLED package method. By implementing surface roughening treatment to the pre glue coating area to obtain a roughened surface and coating seal on the roughened surface, the contact area between the seal and the package cover plate is enlarged and the bonding force between the package cover plate and the substrate is strengthened, and the tightness is raised. The oxygen and the water vapor permeating to the inside of the OLED can be effectively diminished. The performance of the OLED is promoted and the usage lifetime of the OLED element is extended. The present invention provides an OLED package structure. A circle of roughened surface after surface roughening treatment is on the package cover plate, and the seal is positioned on the roughened surface. The contact area between the seal and the package cover plate is enlarged, which is capable of firmly bonding the package cover plate and the substrate. The tightness result is better and the oxygen and the water vapor permeating to the inside of the OLED can be effectively diminished. Accordingly, the performance of the OLED element is promoted and the usage lifetime of the OLED element is extended.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a flowchart of an OLED package method according to the present invention;

FIG. 2 is a diagram of the step 1 according to the OLED package method of the present invention;

FIG. 3 is a diagram of the step 2 according to the OLED package method of the present invention;

FIG. 4 is a sectional diagram corresponding to FIG. 3;

FIG. 5 is a diagram of the step 3 according to the OLED package method of the present invention;

FIG. 6 is a diagram of the step 4 according to the OLED package method of the present invention;

FIG. 7 is a diagram of the step 5 according to the OLED package method of the present invention and a diagram of an OLED package structure of the present invention.

### DETAILED DESCRIPTION OF PREFERRED EMBODIMENTS

For better explaining the technical solution and the effect of the present invention, the present invention will be further described in detail with the accompanying drawings and the specific embodiments.

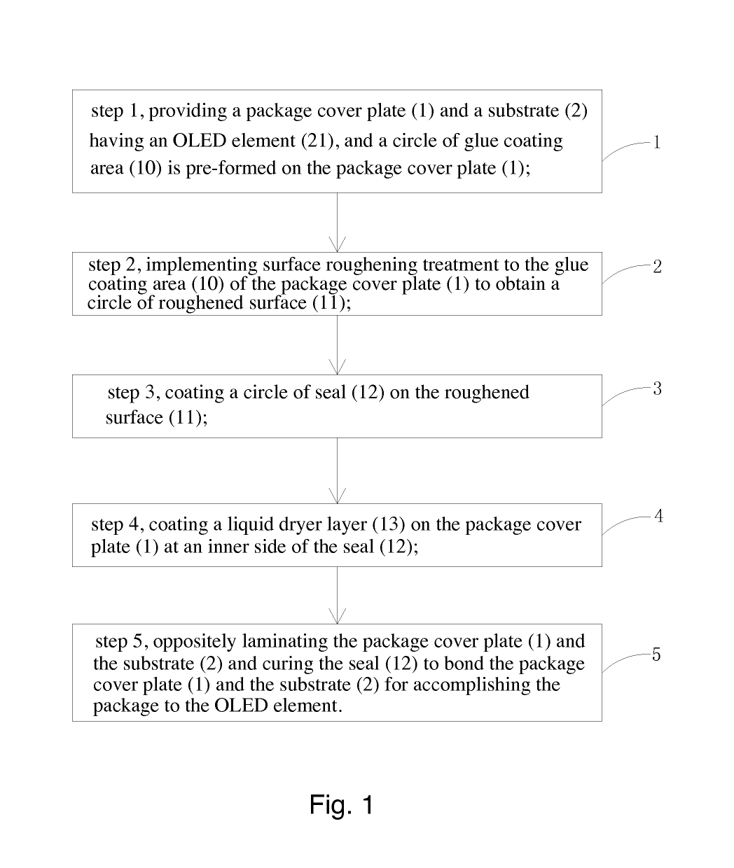

Please refer to FIG. 1. The present invention provides an OLED package method, comprising steps of:

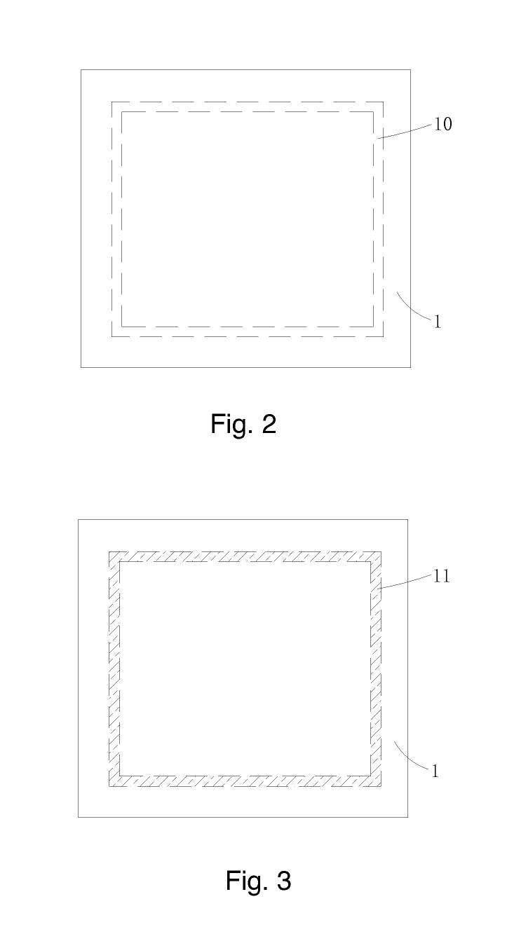

step 1, referring to FIG. 2 and FIG. 7, providing a package cover plate 1 and a substrate 2, and a circle of glue coating area 10 is pre-formed on the package cover plate 1.

Both the package cover plate 1 and the substrate 2 are transparent substrates. Preferably, both the package cover plate 1 and the substrate 2 are glass substrates. The substrate 2 is a substrate having an OLED element 21. Preferably, the substrate 2 is a TFT substrate having the OLED element 21.

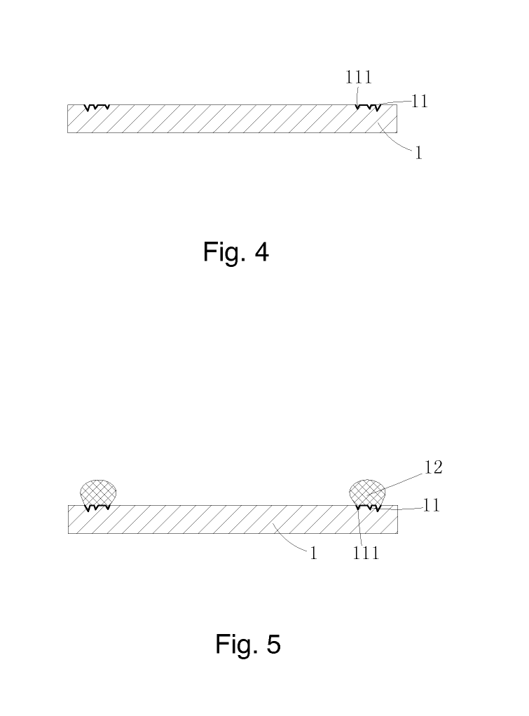

step 2, referring to FIG. 3 and FIG. 4, implementing surface roughening treatment to the glue coating area 10 of the package cover plate 1 to obtain a circle of roughened surface 11.

Specifically, the roughened surface 11 can be obtained by wheel grating or flannelette grating. Furthermore, the roughened surface 11 obtained by wheel grating or flannelette grating comprises irregular friction marks 111 pitted at a surface of the package cover plate 1. Preferably, a depth of the roughened surface 11 is controlled to be under 50 μm.

step 3, as shown in FIG. 5, coating a circle of seal 12 on the roughened surface 11.

The seal 12 is UV curing glue.

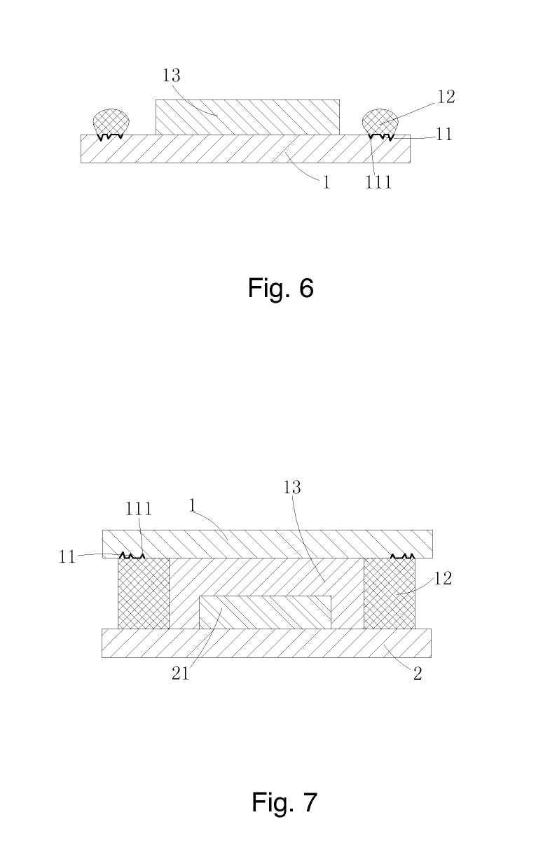

step 4, as shown in FIG. 6, coating a liquid dryer layer 13 on the package cover plate 1 at an inner side of the seal 12.

Specifically, the liquid dryer of production code “OleDry-F” developed by Futaba Corporation is employed as the liquid dryer 13. The liquid dryer is transparent, and has certain viscidity, well moisture absorption ability, and the chemical formula:

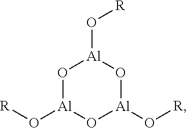

wherein R is a substituent group, such as ethyl (CH3CH2-), etcetera.

step 5, as shown in FIG. 7, oppositely laminating the package cover plate 1 and the substrate 2 and curing the seal 12 to bond the package cover plate 1 and the substrate 2 for accomplishing the package to the OLED element 21.

In the aforesaid OLED package method, the roughened surface 11 is obtained by implementing surface roughening treatment to the glue coating area 10 on the package cover plate 1, and seal 12 is coated on the roughened surface 11 to enlarge the contact area between the seal 12 and the package cover plate 1. Accordingly, the bonding force between the package cover plate 1 and the substrate 2 is strengthened, and the tightness is raised. The oxygen and the water vapor permeating to the inside of the OLED are effectively diminished. Meanwhile, the liquid dryer 13 is filled at an inner side of the seal 12 for absorbing the water vapor invading the inside of the OLED. The performance of the OLED element can be promoted and the usage lifetime of the OLED element can be extended.

Please refer to FIG. 7. The present invention further provides an OLED package structure, comprising a package cover plate 1, a substrate 2 oppositely positioned with the package cover plate 1, an OLED element 21, positioned inside the package cover plate 1 and the substrate 2 and set on the substrate 1, seal 12, positioned at periphery of the OLED element 21 to bond the package cover plate 1 and the substrate 2, a liquid dryer 13 filling at an inner side of the seal 12 and covering the OLED element 21

A circle of roughened surface 11 after surface roughening treatment is on the package cover plate 1, and the seal 12 is positioned on the roughened surface 11.

Specifically, both the package cover plate 1 and the substrate 2 are transparent substrates. Preferably, both the package cover plate 1 and the substrate 2 are glass substrates. The substrate 2 is a substrate having an OLED element 21. Preferably, the substrate 2 is a TFT substrate having the OLED element 21.

The roughened surface 11 can be obtained by wheel grating or flannelette grating. The roughened surface 11 comprises irregular friction marks 111 pitted at a surface of the package cover plate 1. Furthermore, a depth of the roughened surface 11 is controlled to be under 50 μm.

The liquid dryer of production code “OleDry-F” developed by Futaba Corporation is employed as the liquid dryer 13. The liquid dryer is transparent, and has certain viscidity, well moisture absorption ability, and the chemical formula:

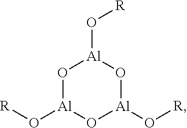

wherein R is a substituent group, such as ethyl (CH3CH2-), etcetera.

In the aforesaid OLED package structure, a circle of roughened surface 11 after surface roughening treatment is on the package cover plate 1, and the seal 12 is positioned on the roughened surface 11 to enlarge the contact area between the seal 12 and the package cover plate 1 and strengthen the bonding force between the seal 12 and the package cover plate 1. The package cover plate 1 and the substrate 2 can be firmly bonded, and the tightness result is better. The oxygen and the water vapor permeating to the inside of the OLED can be effectively diminished. Meanwhile, the liquid dryer layer 13 is filled at an inner side of the seal 12 for absorbing the water vapor invading the inside of the OLED. Accordingly, the performance of the OLED element can be promoted and the usage lifetime of the OLED element can be extended.

In conclusion, by implementing surface roughening treatment to the pre glue coating area to obtain a roughened surface and coating seal on the roughened surface, the OLED package method of the present invention enlarges the contact area between the seal and the package cover plate and strengthens the bonding force between the package cover plate and the substrate, and the tightness is raised. The oxygen and the water vapor permeating to the inside of the OLED can be effectively diminished. The performance of the OLED is promoted and the usage lifetime of the OLED element is extended. With a circle of roughened surface after surface roughening treatment is on the package cover plate, and the seal is positioned on the roughened surface, the OLED package structure of the present invention enlarges the contact area between the seal and the package cover plate and is capable of firmly bonding the package cover plate and the substrate. The tightness result is better and the oxygen and the water vapor permeating to the inside of the OLED can be effectively diminished. Accordingly, the performance of the OLED element is promoted and the usage lifetime of the OLED element is extended.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

1. An OLED package method, comprising steps of:
step 1, providing a package cover plate and a substrate having an OLED element, and a circle of glue coating area is pre-formed on the package cover plate;
step 2, implementing surface roughening treatment to the glue coating area of the package cover plate to obtain a circle of roughened surface;
step 3, coating a circle of seal on the roughened surface;
step 4, coating a liquid dryer layer on the package cover plate at an inner side of the seal;
step 5, oppositely laminating the package cover plate and the substrate and curing the seal to bond the package cover plate and the substrate for accomplishing the package to the OLED element.

2. The OLED package method according to claim 1, wherein both the package cover plate and the substrate are glass substrates.

3. The OLED package method according to claim 1, wherein the roughened surface in the step 2 is obtained by wheel grating or flannelette grating.

4. The OLED package method according to claim 1, wherein the roughened surface comprises irregular friction marks pitted at a surface of the package cover plate.

5. The OLED package method according to claim 4, wherein a depth of the roughened surface is not more than 50 μm.

6. The OLED package method according to claim 1, wherein the seal in the step 5 is cured by ultraviolet light irradiation.

7. An organic light emitting diode (OLED) package structure, comprising a package cover plate, a substrate oppositely positioned with the package cover plate, an OLED element, positioned inside the package cover plate and the substrate and set on the substrate, seal, positioned at periphery of the OLED element to bond the package cover plate and the substrate, a liquid dryer filling at an inner side of the seal and covering the OLED element; a circle of roughened surface after surface roughening treatment is on the package cover plate, and the seal is positioned on the roughened surface.

8. The OLED package structure according to claim 7, wherein the roughened surface comprises irregular friction marks pitted at a surface of the package cover plate.

9. The OLED package structure according to claim 8, wherein a depth of the roughened surface is not more than 50 μm.

10. The OLED package structure according to claim 7, wherein both the package cover plate and the substrate are glass substrates.

11. An organic light emitting diode (OLED) package structure, comprising a package cover plate, a substrate oppositely positioned with the package cover plate, an OLED element, positioned inside the package cover plate and the substrate and set on the substrate, seal, positioned at periphery of the OLED element to bond the package cover plate and the substrate, a liquid dryer filling at an inner side of the seal and covering the OLED element; a circle of roughened surface after surface roughening treatment is on the package cover plate, and the seal is positioned on the roughened surface;
wherein the roughened surface comprises irregular friction marks pitted at a surface of the package cover plate;
wherein both the package cover plate and the substrate are glass substrates.

12. The OLED package structure according to claim 11, wherein a depth of the roughened surface is not more than 50 μm.
